(19) United States
(12) Patent Application Publication
(10) Pub. No.: US 2024/0313741 A1
(43) Pub. Date: Sep. 19, 2024

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/667,447

(22) Filed: May 17, 2024

Related U.S. Application Data
(63) Continuation of application No. PCT/JP2022/042920, filed on Nov. 18, 2022.
(60) Provisional application No. 63/281,101, filed on Nov. 19, 2021.

(51) Int. Cl. H03H 9/17; H03H 9/02; H03H 9/05; H03H 9/10

(52) U.S. Cl. CPC H03H 9/178; H03H 9/02031; H03H 9/02157; H03H 9/02228; H03H 9/0523; H03H 9/105; H03H 9/173

(57) ABSTRACT

An acoustic wave device includes first and second piezoelectric layers and an IDT electrode. The second piezoelectric layer is located above the first piezoelectric layer in a first direction. The IDT electrode includes first and second busbar electrodes and first and second electrode fingers. The first and second busbar electrodes oppose each other. The first electrode finger is provided to the first busbar electrode and extends toward the second busbar electrode. The second electrode finger is provided to the second busbar electrode and extends toward the first busbar electrode. The first and second electrode fingers are sandwiched between the first and second piezoelectric layers in the first direction. The first and second electrode fingers extend in a second direction which intersects with the first direction and are located to overlap each other as seen in a third direction perpendicular or substantially perpendicular to the second direction.

### CROSS REFERENCE TO RELATED APPLICATIONS

This application claims the benefit of priority to Provisional Application No. 63/281,101, filed on Nov. 19, 2021, and is a Continuation Application of PCT Application No. PCT/JP2022/042920, filed on Nov. 18, 2022. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 discloses an acoustic wave device.

In the acoustic wave device disclosed in Japanese Unexamined Patent Application Publication No. 2012-257019, the coupling coefficient is determined by a ratio of the thickness of a piezoelectric layer to a pitch between electrode fingers. To manufacture an acoustic wave device having a high coupling coefficient, it is necessary to increase the pitch between the electrode fingers. This may enlarge the size of the acoustic wave device.

### SUMMARY OF THE INVENTION

Example embodiments of the present invention reduce the size of acoustic wave devices.

An acoustic wave device according to an example embodiment of the present invention includes first and second piezoelectric layers and an interdigital transducer (IDT) electrode. The second piezoelectric layer is located above the first piezoelectric layer in a first direction. The IDT electrode includes first and second busbar electrodes and first and second electrode fingers. The first busbar electrode and the second busbar electrode oppose each other. The first electrode finger is provided to the first busbar electrode and extends toward the second busbar electrode. The second electrode finger is provided to the second busbar electrode and extends toward the first busbar electrode. The first and second electrode fingers are sandwiched between the first piezoelectric layer and the second piezoelectric layer in the first direction. The first and second electrode fingers extend in a second direction which intersects with the first direction and are located to overlap each other as seen in a third direction which is perpendicular or substantially perpendicular to the second direction.

According to example embodiments of the present invention, it is possible to reduce the size of acoustic wave devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to a first example embodiment of the present invention.

FIG. 1B is a plan view of an electrode structure of the first example embodiment of the present invention.

FIG. 2 is a sectional view taken along line II-II in FIG. 1A.

FIG. 3A is a schematic sectional view explaining a Lamb wave propagating through a piezoelectric layer in a comparative example.

FIG. 3B is a schematic sectional view explaining a bulk wave of a thickness shear primary mode propagating through a piezoelectric layer in the first example embodiment of the present invention.

FIG. 4 is a schematic sectional view explaining the amplitude direction of a bulk wave of the thickness shear primary mode propagating through the piezoelectric layer in the first example embodiment of the present invention.

FIG. 5 is a graph illustrating an example of resonance characteristics of the acoustic wave device of the first example embodiment of the present invention.

FIG. 6 is a graph illustrating, regarding the acoustic wave device of the first example embodiment of the present invention, the relationship between d/2p, where d is the average thickness of the piezoelectric layer and p is the center-to-center distance or the average center-to-center distance between adjacent electrodes, and the fractional bandwidth of the acoustic wave device as a resonator.

FIG. 7 is a plan view illustrating an example in which a pair of electrodes is provided in the acoustic wave device of the first example embodiment of the present invention.

FIG. 8 is a reference graph illustrating an example of the resonance characteristics of the acoustic wave device of the first example embodiment of the present invention.

FIG. 9 is a diagram illustrating the relationship between the fractional bandwidth of many acoustic wave resonators formed based on the acoustic wave device of the first example embodiment of the present invention and the amount of phase shift of the impedance of a spurious response normalized at 180 degrees as the magnitude of the spurious response.

FIG. 10 is a graph illustrating the relationships between d/2p, the metallization ratio MR, and the fractional bandwidth.

FIG. 11 is a graph illustrating a map of the fractional bandwidth with respect to the Euler angles (0°, θ, ψ) of LiNbO₃ in a case in which d/p is approached as close to 0 as possible.

FIG. 12 is a partial cutaway perspective view explaining an acoustic wave device according to an example embodiment of the present invention.

FIG. 13 is a schematic sectional view illustrating a first example of the acoustic wave device of the first example embodiment of the present invention.

FIG. 14 is an enlarged sectional view illustrating a region E in FIG. 13.

FIG. 15 is an enlarged sectional view illustrating a second example of the acoustic wave device of the first example embodiment of the present invention.

FIG. 16 is an enlarged sectional view illustrating a third example of the acoustic wave device of the first example embodiment of the present invention.

FIG. 17 is an enlarged sectional view illustrating an acoustic wave device of a first comparative example.

FIG. 18 is an enlarged sectional view illustrating an acoustic wave device of a second comparative example.

FIG. 19 is a graph illustrating admittance characteristics of the acoustic wave devices of the first test example and the first comparative example.

FIG. 20 is a graph illustrating admittance characteristics of the acoustic wave devices of the first test example and the second comparative example.

FIG. 21 is a graph illustrating admittance characteristics of the acoustic wave devices of the first and second test examples.

### DETAILED DESCRIPTION OF THE EXAMPLE EMBODIMENTS

Example embodiments of the present invention will be described below in detail with reference to the drawings. However, the example embodiments are not provided to restrict the present invention. The individual example embodiments described in the disclosure are only examples and the configurations discussed in different example embodiments may partially be replaced by or combined with each other. Regarding modified examples and second and subsequent example embodiments, reference will be given only to the configuration different from that of a first example embodiment while an explanation of the same configuration as the first example embodiment is being omitted. Similar advantages obtained by similar configurations are not repeated every time an example embodiment is explained.

### First Example Embodiment

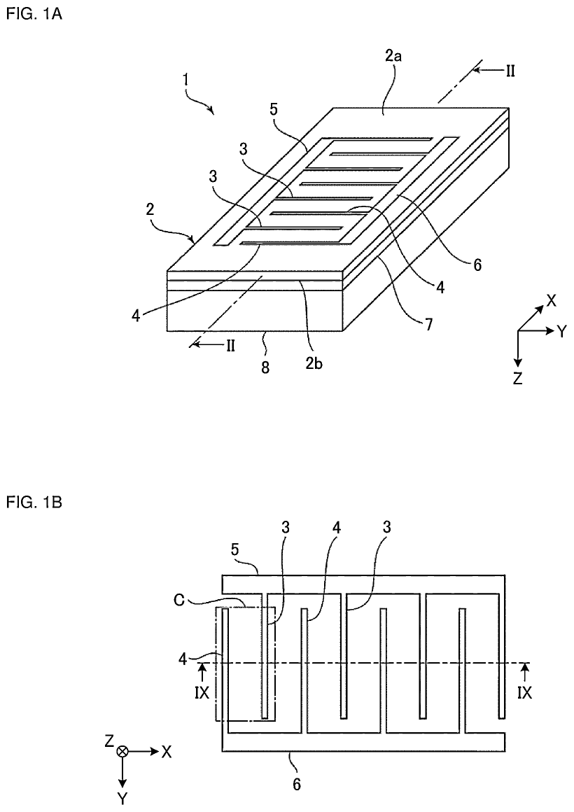

FIG. 1A is a perspective view of an acoustic wave device according to the first example embodiment. FIG. 1B is a plan view of the electrode structure of the first example embodiment.

An acoustic wave device 1 of the first example embodiment includes a piezoelectric layer 2 made of LiNbO₃, for example. The piezoelectric layer 2 may alternatively be made of LiTaO₃, for example. The cut-angles of LiNbO₃ or LiTaO₃ in the first example embodiment are preferably Z-cut, for example, but may be rotated Y-cut or X-cut. Preferably, for example, the propagation orientation of the cut-angles of LiNbO₃ or LiTaO₃ is Y-propagation about ±30° and X-propagation about ±30°.

The thickness of the piezoelectric layer 2 is not limited to a particular thickness, but, for example it is preferably about 50 to about 1000 nm to effectively excite the thickness shear primary mode.

The piezoelectric layer 2 includes first and second main surfaces 2a and 2b opposing each other in the Z direction. On the first main surface 2a, electrode fingers 3 and 4 are provided.

The electrode finger 3 is an example of a “first electrode finger”, while the electrode finger 4 is an example of a “second electrode finger”. In FIGS. 1A and 1B, the plural electrode fingers 3 are plural “first electrode fingers” connected to a first busbar electrode 5, while the plural electrode fingers 4 are plural “second electrode fingers” connected to a second busbar electrode 6. The plural electrode fingers 3 and the plural electrode fingers 4 are interdigitated with each other. This defines an IDT (Interdigital Transducer) electrode including the electrode fingers 3 and 4 and the first and second busbar electrodes 5 and 6.

The IDT electrode is defined by first and second comb-shaped electrodes.

The first comb-shaped electrode includes a first busbar electrode 5 and a first electrode finger 3. The first electrode finger 3 extends in a second direction in a plane of a piezoelectric substrate and one end of the first electrode finger 3 is connected to the first busbar electrode 5. If plural first electrode fingers 3 are provided, a conductor to which one end of each of the plural electrode fingers 3 is connected is the first busbar electrode 5. The first busbar electrode 5 may be integrally provided with a connection wiring connected to another element or terminal.

The second comb-shaped electrode includes a second busbar electrode 6 and a second electrode finger 4. The second electrode finger 4 extends in the second direction in a plane of the piezoelectric substrate and one end of the second electrode finger 4 is connected to the second busbar electrode 6. If plural second electrode fingers 4 are provided, a conductor to which one end of each of the plural second electrode fingers 4 is connected is the second busbar electrode 6. The second busbar electrode 6 may be integrally provided with a connection wiring connected to another element or terminal.

The first and second comb-shaped electrodes are at least partially interdigitated with each other. The first and second busbar electrodes 5 and 6 oppose each other in a second direction, which will be discussed later. The first electrode fingers 3 and the second electrode fingers 4 oppose each other in a third direction, which will be discussed later. That is, at least some of the first electrode fingers 3 and at least some of the second electrode fingers 4 are arranged alternately in the third direction. The first electrode fingers 3 and the second electrode fingers 4 which are arranged alternately in the third direction overlap each other in the third direction.

The electrode fingers 3 and 4 have a rectangular or substantially rectangular shape and have a longitudinal direction. An electrode finger 3 and an adjacent electrode finger 4 oppose each other in a direction perpendicular or substantially perpendicular to this longitudinal direction. The longitudinal direction of the electrode fingers 3 and 4 and the direction perpendicular or substantially perpendicular to the longitudinal direction of the electrode fingers 3 and 4 are directions intersecting with the thickness direction of the piezoelectric layer 2. It can thus be said that an electrode finger 3 and an adjacent electrode finger 4 oppose each other in a direction intersecting with the thickness direction of the piezoelectric layer 2. In the following description, an explanation may be given, assuming that the thickness direction of the piezoelectric layer 2 is the Z direction (or a first direction), the longitudinal direction of the electrode fingers 3 and 4 is the Y direction (or a second direction), and the direction perpendicular or substantially perpendicular to the longitudinal direction of the electrode fingers 3 and 4 is the X direction (or a third direction).

The electrode fingers 3 and 4 may extend in a direction perpendicular or substantially perpendicular to the longitudinal direction of the electrode fingers 3 and 4 shown in FIGS. 1A and 1B. That is, the electrode fingers 3 and 4 may extend in the extending direction of the first busbar electrode 5 and the second busbar electrode 6 shown in FIGS. 1A and 1B. In this case, the first busbar electrode 5 and the second busbar electrode 6 extend in the extending direction of the electrode fingers 3 and 4 shown in FIGS. 1A and 1B. Multiple pairs of electrode fingers 3 and electrode fingers 4, each pair including an electrode finger 3, which is connected to one potential, and an electrode finger 4, which is connected to the other potential, adjacent to each other, are arranged in the direction perpendicular or substantially perpendicular to the longitudinal direction of the electrode fingers 3 and 4.

“Electrode fingers 3 and 4 adjacent to each other” refers to, not that the electrode fingers 3 and 4 are located to directly contact each other, but that the electrode fingers 3 and 4 are located with a space therebetween. When electrode fingers 3 and 4 are adjacent to each other, an electrode connected to a hot electrode and an electrode connected to a ground electrode, including the other electrode fingers 3 and 4, are not located between the adjacent electrode fingers 3 and 4. The number of pairs of electrode fingers 3 and 4 is not necessarily an integral number and may be 1.5 or 2.5, for example.

The center-to-center distance, that is, the pitch, between the electrode fingers 3 and 4 is, for example, preferably about 1 to about 10 μm. The center-to-center distance between the electrode fingers 3 and 4 is a distance from the center of the width of the electrode finger 3 in the direction perpendicular or substantially perpendicular to the longitudinal direction of the electrode finger 3 to that of the electrode finger 4 in the direction perpendicular or substantially perpendicular to the longitudinal direction of the electrode finger 4.

When at least one of the number of electrode fingers 3 and the number of electrode fingers 4 is plural (when 1.5 or more pairs of electrode fingers 3 and 4, each pair being formed by an electrode finger 3 and an electrode finger 4, are provided), the center-to-center distance between the electrode fingers 3 and 4 is the average value of that between adjacent electrode fingers 3 and 4 of the 1.5 or more pairs.

The width of each of the electrode fingers 3 and 4, that is, the dimension in the facing direction of the electrode fingers 3 and 4, is, for example, preferably about 150 to about 1000 nm. The center-to-center distance between the electrode fingers 3 and 4 is a distance from the center of a dimension (width) of the electrode finger 3 in the direction perpendicular or substantially perpendicular to the longitudinal direction of the electrode finger 3 to that of the electrode finger 4 in the direction perpendicular or substantially perpendicular to the longitudinal direction of the electrode finger 4.

In the first example embodiment, since a Z-cut piezoelectric layer is used, the direction perpendicular or substantially perpendicular to the longitudinal direction of the electrode fingers 3 and 4 is a direction perpendicular or substantially perpendicular to the polarization direction of the piezoelectric layer 2. However, this is not the case if a piezoelectric layer of another cut angle is used as the piezoelectric layer 2. “Being perpendicular” does not necessarily mean being exactly perpendicular, but may mean being substantially perpendicular. For example, the angle between the direction perpendicular to the longitudinal direction of the electrode fingers 3 and 4 and the polarization direction may be in a range of about 90°±10°, for example.

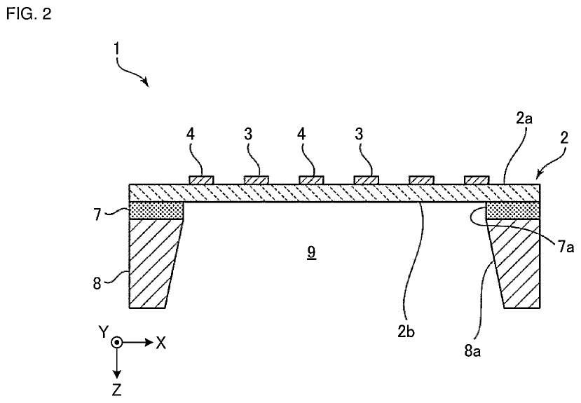

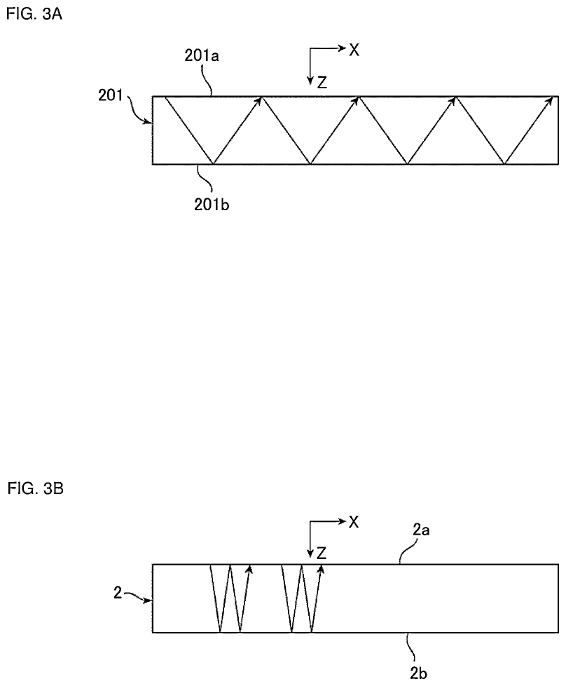

A support substrate 8 is stacked below the second main surface 2b of the piezoelectric layer 2 with an intermediate layer 7 interposed therebetween. The intermediate layer 7 and the support substrate 8 have a frame shape and include cavities 7a and 8a, respectively, as shown in FIG. 2. With this structure, a space (air gap) 9 is provided.

The space 9 is provided not to interfere with the vibration of an excitation region C of the piezoelectric layer 2. Hence, the support substrate 8 is stacked below the second main surface 2b with the intermediate layer 7 therebetween and is located at a position at which the support substrate 8 does not overlap a region where at least one pair of electrode fingers 3 and 4 is located. The provision of the intermediate layer 7 may be omitted. The support substrate 8 can thus be stacked directly or indirectly below the second main surface 2b of the piezoelectric layer 2.

The intermediate layer 7 is preferably made of silicon oxide, for example. Instead of silicon oxide, another suitable insulating material, such as silicon nitride or alumina, for example, may be used to form the intermediate layer 7 if so desired.

The support substrate 8 is preferably made of Si, for example. The plane orientation of Si on the side of the piezoelectric layer 2 may be (100), (110), or (111). Preferably, high-resistivity Si, such as Si having a resistivity of, for example, about 4 kΩ or higher, is used. A suitable insulating material or semiconductor material may be used for the support substrate 8. Examples of the material for the support substrate 8 are: piezoelectric materials, such as aluminum oxide, lithium tantalate, lithium niobate, and quartz; various ceramic materials, such as alumina, magnesia, sapphire, silicon nitride, aluminum nitride, silicon carbide, zirconia, cordierite, mullite, steatite, and forsterite; dielectric materials, such as diamond and glass; and semiconductor materials, such as gallium nitride.

The above-described plural electrode fingers 3 and 4 and first and second busbar electrodes 5 and 6 are made of a suitable metal or alloy, such as Al or an AlCu alloy, for example. In the first example embodiment, the electrode fingers 3 and 4 and the first and second busbar electrodes 5 and 6 have a structure in which an Al film is stacked on a Ti film, for example. A contact layer made of a material other than Ti may be used.

To drive the acoustic wave device 1, an AC voltage is applied to between the plural electrode fingers 3 and the plural electrode fingers 4. More specifically, an AC voltage is applied to between the first busbar electrode 5 and the second busbar electrode 6. With the application of the AC voltage, resonance characteristics based on a bulk wave of the thickness shear primary mode excited in the piezoelectric layer 2 can be obtained.

In the acoustic wave device 1, for example, d/p is set to about 0.5 or smaller, where d is the thickness of the piezoelectric layer 2 and p is the center-to-center distance between adjacent electrode fingers 3 and 4 defining one of multiple pairs of electrode fingers 3 and 4. This can effectively excite a bulk wave of the thickness shear primary mode and obtain high resonance characteristics. More preferably, for example, d/p is about 0.24 or smaller, in which case, even higher resonance characteristics can be obtained.

As in the first example embodiment, when at least one of the number of electrode fingers 3 and the number of electrode fingers 4 is plural, that is, when 1.5 or more pairs of electrode fingers 3 and 4, each pair being defined by an electrode finger 3 and an electrode finger 4, are provided, the average center-to-center distance between adjacent electrode fingers 3 and 4 of the individual pairs is used as the center-to-center distance between adjacent electrode fingers 3 and 4.

The acoustic wave device 1 of the first example embodiment is configured as described above. Thus, even if the number of pairs of the electrode fingers 3 and 4 is reduced to miniaturize the acoustic wave device 1, the Q factor is unlikely to be lowered. This is because the acoustic wave device 1 is a resonator which does not require reflectors on both sides and only a small propagation loss is incurred. The reason why the acoustic wave device 1 does not require reflectors is that a bulk wave of the thickness shear primary mode is utilized.

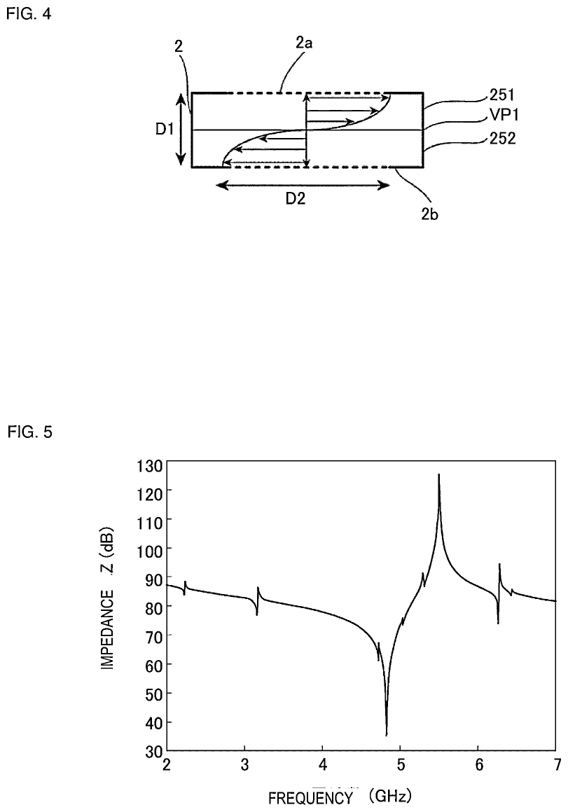

FIG. 3A is a schematic sectional view explaining a Lamb wave propagating through a piezoelectric layer in a comparative example. FIG. 3B is a schematic sectional view explaining a bulk wave of the thickness shear primary mode propagating through the piezoelectric layer in the first example embodiment. FIG. 4 is a schematic sectional view explaining the amplitude direction of a bulk wave of the thickness shear primary mode propagating through the piezoelectric layer in the first example embodiment.

FIG. 3A shows a Lamb wave propagating through the piezoelectric layer in an acoustic wave device, such as that disclosed in Japanese Unexamined Patent Application Publication No. 2012-257019. As illustrated in FIG. 3A, a wave propagates through a piezoelectric layer 201 as indicated by the arrows. The piezoelectric layer 201 has a first main surface 201a and a second main surface 201b, and the thickness direction in which the first main surface 201a and the second main surface 201b are linked with each other is the Z direction. The X direction is a direction in which the electrode fingers 3 and 4 of an IDT electrode are arranged. As illustrated in FIG. 3A, a Lamb wave propagates in the X direction. Because of the characteristics of a Lamb wave, while the piezoelectric film 201 is entirely vibrated, the Lamb wave propagates in the X direction, and thus, reflectors are located on both sides to obtain resonance characteristics. Because of these characteristics, a propagation loss is incurred in the wave. If the size of the acoustic wave device is reduced, that is, if the number of pairs of electrode fingers is reduced, the Q factor is lowered.

In contrast, as illustrated in FIG. 3B, in the acoustic wave device of the first example embodiment, since the vibration displacement direction is the thickness shear direction, a wave propagates and resonates substantially in a direction in which the first main surface 2a and the second main surface 2b of the piezoelectric layer 2 are linked with each other, namely, substantially in the Z direction. That is, the X-direction components of the wave are much smaller than the Z-direction components. The resonance characteristics are obtained as a result of the wave propagating in the Z direction, and thus, the acoustic wave device does not require reflectors. Hence, a propagation loss, which would be caused by the propagation of a wave to reflectors, is not incurred. Even if the number of pairs of the electrode fingers 3 and 4 is reduced to miniaturize the acoustic wave device, the Q factor is unlikely to be lowered.

Regarding the amplitude direction of a bulk wave of the thickness shear primary mode, as shown in FIG. 4, the amplitude direction in a first region 251 included in the excitation region C (see FIG. 1B) of the piezoelectric layer 2, and that in a second region 252 included in the excitation region C, are opposite directions. In FIG. 4, a bulk wave generated as a result of a voltage being applied to between the electrode fingers 3 and 4 so that the potential of the electrode finger 4 becomes higher than that of the electrode finger 3 is schematically illustrated. The first region 251, which is part of the excitation region C, is a region between a virtual plane VP1 and the first main surface 2a. The virtual plane VP1 is a plane which divides the piezoelectric layer 2 into two regions in a direction perpendicular or substantially perpendicular to the thickness direction of the piezoelectric layer 2. The second region 252, which is part of the excitation region C, is a region between the virtual plane VP1 and the second main surface 2b.

As discussed above, in the acoustic wave device 1, at least one pair of electrode fingers 3 and 4 is provided. Since a wave does not propagate through the piezoelectric layer 2 of the acoustic wave device 1 in the X direction, plural pairs of electrode fingers 3 and 4 are not required. That is, the provision of at least one pair of electrodes is sufficient, however additional pairs of electrodes can be provided if so desired.

In one example, the electrode finger 3 is an electrode connected to a hot potential, while the electrode finger 4 is an electrode connected to a ground potential. Conversely, the electrode finger 3 may be connected to a ground potential, while the electrode finger 4 may be connected to a hot potential. In the first example embodiment, as described above, at least one pair of electrodes is connected to a hot potential and a ground potential, and more specifically, one electrode forming this pair is an electrode connected to a hot potential, and the other electrode is an electrode connected to a ground potential. No floating electrode is located.

FIG. 5 is a graph illustrating an example of the resonance characteristics of the acoustic wave device of the first example embodiment. The design parameters of the acoustic wave device 1 that has obtained the resonance characteristics shown in FIG. 5 are as follows.
Piezoelectric layer 2: LiNbO₃ having the Euler angles of (0°, 0°, 90°)
Thickness of piezoelectric layer 2: about 400 nm
Length of excitation region C (see FIG. 1B): about 40 μm
Number of pairs of electrode fingers 3 and 4: 21
Center-to-center distance (pitch) between electrode fingers 3 and 4: about 3 μm
Width of electrode fingers 3 and 4: about 500 nm d/p: about 0.133
Intermediate layer 7: silicon oxide film having a thickness of about 1 μm
Support substrate 8: Si

The excitation region C (see FIG. 1B) is a region where the electrode fingers 3 and 4 overlap each other as seen from the X direction perpendicular or substantially perpendicular to the longitudinal direction of the electrode fingers 3 and 4. The length of the excitation region C is a dimension of the excitation region C in the longitudinal direction of the electrode fingers 3 and 4. The excitation region C is an example of an “overlapping region”.

In the first example embodiment, the center-to-center distance of an electrode pair defined by an electrode finger 3 and an electrode finger 4 was set to all be equal or substantially equal among plural pairs. That is, the electrode fingers 3 and 4 were located at equal or substantially equal pitches.

As is seen from FIG. 5, despite the fact that no reflectors are provided, high resonance characteristics having a fractional bandwidth of about 12.5% are obtained.

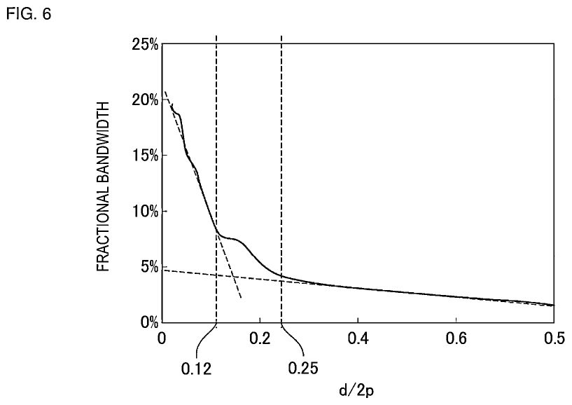

In the first example embodiment, for example, as stated above, d/p is about 0.5 or smaller, and more preferably, d/p is about 0.24 or smaller, where d is the thickness of the piezoelectric layer 2 and p is the center-to-center distance between the electrode fingers 3 and 4. This will be explained below with reference to FIG. 6.

Plural acoustic wave devices were made in a manner the same as or similar to the acoustic wave device which has obtained the resonance characteristics shown in FIG. 5, except that d/2p was varied among these plural acoustic wave devices. FIG. 6 is a graph illustrating, regarding the acoustic wave device 1 of the first example embodiment, the relationship between d/2p, where d is the average thickness of the piezoelectric layer 2 and p is the center-to-center distance or the average center-to-center distance between adjacent electrodes, and the fractional bandwidth of the acoustic wave device 1 as a resonator.

As is seen from FIG. 6, when d/2p exceeds about 0.25, that is, d/p >about 0.5, the fractional bandwidth remains less than about 5% even if d/p is changed. In contrast, when d/2p≤about 0.25, that is, when d/p≤about 0.5, the fractional bandwidth can be improved to about 5% or higher as long as d/p is changed in this range. It is thus possible to provide a resonator having a high coupling coefficient. When d/2p is about 0.12 or smaller, that is, when d/p is about 0.24 or smaller, the fractional bandwidth can be improved to about 7% or higher. Additionally, if d/p is adjusted in this range, a resonator having an even higher fractional bandwidth can be obtained. It is thus possible to form a resonator having an even higher coupling coefficient. Thus, it has been validated that, as a result of setting d/p to about 0.5 or smaller, a resonator utilizing a bulk wave of the thickness shear primary mode and exhibiting a high coupling coefficient can be provided.

As stated above, at least one pair of electrodes may be only one pair of electrodes. If one pair of electrodes is provided, the center-to-center distance between the adjacent electrode fingers 3 and 4 is used as the above-described center-to-center distance p. If 1.5 or more pairs of electrodes are provided, the average center-to-center distance between the adjacent electrode fingers 3 and 4 of the individual pairs is used as the center-to-center distance p.

Regarding the thickness d of the piezoelectric layer 2, if the piezoelectric layer 2 has variations in the thickness, the averaged thickness value may be used.

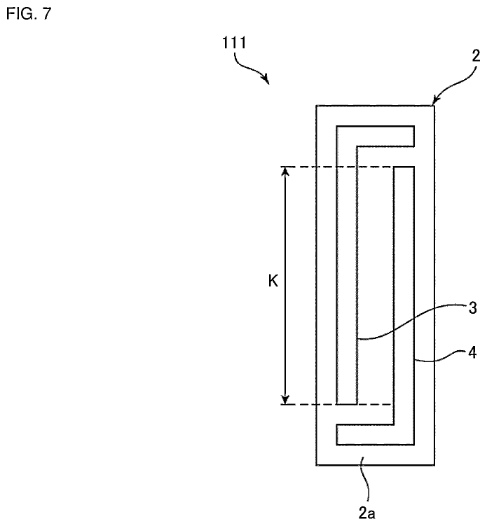

FIG. 7 is a plan view illustrating an example in which a pair of electrodes is provided in the acoustic wave device of the first example embodiment. In an acoustic wave device 101, a pair of electrodes including electrode fingers 3 and 4 is provided on the first main surface 2a of the piezoelectric layer 2. K in FIG. 7 indicates the overlapping width of the electrode fingers 3 and 4. As stated above, in the acoustic wave device of the present disclosure, only one pair of electrodes may be provided. In this case, too, a bulk wave of the thickness shear primary mode can be effectively excited if the above-described d/p is about 0.5 or smaller.

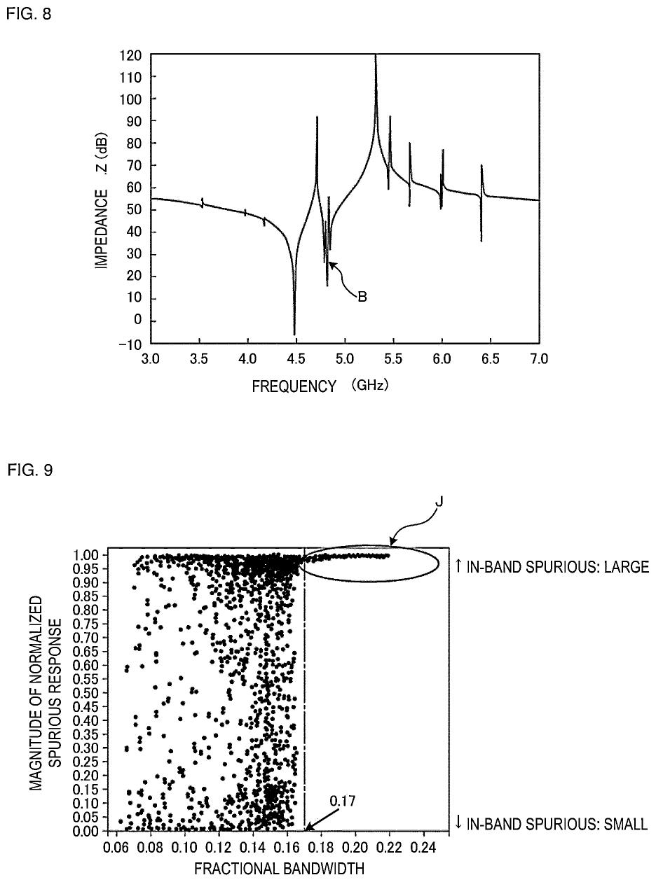

In the acoustic wave device 1, the metallization ratio MR of any one pair of adjacent electrode fingers 3 and 4 among the plural electrode fingers 3 and 4 to the excitation region C where this pair of electrode fingers 3 and 4 overlap each other as seen in their facing direction preferably satisfies MR≤about 1.75 (d/p)+0.075. In this case, spurious responses can be effectively reduced. This will be explained below with reference to FIGS. 8 and 9.

FIG. 8 is a reference graph illustrating an example of the resonance characteristics of the acoustic wave device of the first example embodiment. The spurious response indicated by the arrow B is observed between the resonant frequency and the anti-resonant frequency. d/p was set to about 0.08, and the Euler angles of LiNbO₃ were set to (0°, 0°, 90°). The metallization ratio MR was set to about 0.35.

The metallization ratio MR will be explained below with reference to FIG. 1B. In the electrode structure in FIG. 1B, a pair of electrode fingers 3 and 4 will be focused, and it is assumed that only this pair is provided. In this case, the portion defined by the long dashed dotted lines is the excitation region C. The excitation region C is a region where the electrode finger 3 overlaps the electrode finger 4, a region where the electrode finger 4 overlaps the electrode finger 3, and a region where the electrode fingers 3 and 4 overlap each other in the region between the electrode fingers 3 and 4, when the electrode fingers 3 and 4 are seen in the direction perpendicular or substantially perpendicular to the longitudinal direction thereof, that is, in the facing direction of the electrode fingers 3 and 4. The area of the electrode fingers 3 and 4 within the excitation region C to the area of the excitation region C is the metallization ratio MR. That is, the metallization ratio MR is a ratio of the area of a metallized portion to the area of the excitation region C.

If plural pairs of electrode fingers 3 and 4 are provided, the ratio of the areas of the metallized portions included in the total excitation region to the total area of the excitation region is used as the metallization ratio MR.

Many acoustic wave resonators were formed based on the acoustic wave device of the first example embodiment. FIG. 9 is a diagram illustrating the relationship between the fractional bandwidth and the amount of phase shift of the impedance of a spurious response normalized at about 180 degrees as the magnitude of a spurious response. The fractional bandwidth was adjusted by variously changing the film thickness of the piezoelectric layer 2 and the dimensions of electrode fingers 3 and 4. The results shown in FIG. 9 are obtained when the piezoelectric layer 2 made of Z-cut LiNbO₃ was used. Similar results are also obtained if the piezoelectric layer 2 having another cut-angle is used.

A spurious response is as high as about 1.0 in the region defined by the elliptical portion J in FIG. 9. As is seen from FIG. 9, when the fractional bandwidth exceeds about 0.17, that is, about 17%, a large spurious response of about 1 or higher is observed within the pass band even if the parameters which determine the fractional bandwidth are changed. That is, as in the resonance characteristics in FIG. 8, a large spurious response indicated by the arrow B is observed within the pass band. Accordingly, the fractional bandwidth is preferably about 17% or lower. In this case, the spurious response can be reduced by the adjustment of the parameters, such as the film thickness of the piezoelectric layer 2 and the dimensions of electrode fingers 3 and 4.

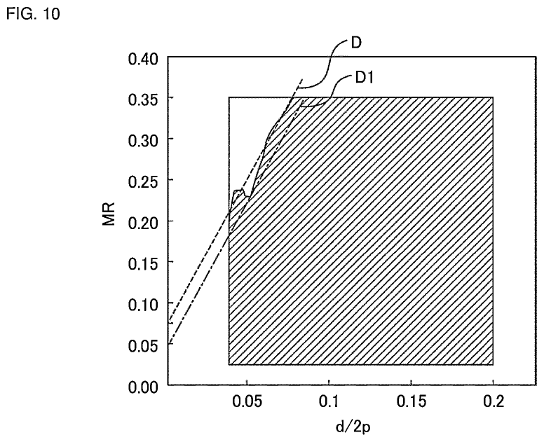

FIG. 10 is a graph illustrating the relationships between d/2p, the metallization ratio MR, and the fractional bandwidth. Based on the acoustic wave device 1 of the first example embodiment, various acoustic wave devices 1 were made by changing d/2p and MR. Then, the fractional bandwidth was measured. The hatched portion on the right side of the broken line D in FIG. 10 is a region where the fractional bandwidth is about 17% or lower. The boundary between the hatched portion and a portion without can be expressed by MR=about 3.5 (d/2p)+0.075, that is, MR=about 1.75 (d/p)+0.075. Preferably, MR≤about 1.75 (d/p)+0.075, in which case, the fractional bandwidth is likely to be about 17% or lower. More preferably, the region where the fractional bandwidth is about 17% or lower is the region on the right side of the boundary expressed by MR=about 3.5 (d/2p)+0.05, which is indicated by the long dashed dotted line D1 in FIG. 10. That is, if MR≤about 1.75 (d/p)+0.05, the fractional bandwidth can reliably be about 17% or lower.

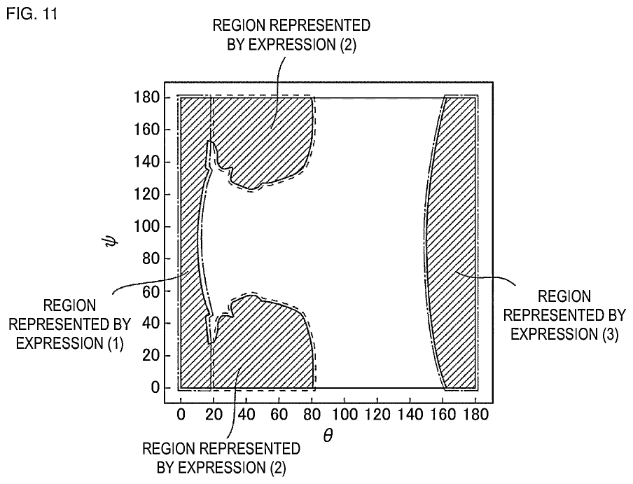

FIG. 11 is a graph illustrating a map of the fractional bandwidth with respect to the Euler angles (0°, θ, ψ) of LiNbO₃ in a case in which d/p is approached as close to 0 as possible. The hatched portions in FIG. 11 are regions where a fractional bandwidth of at least about 5% or higher is obtained. The ranges of the regions can approximate to the ranges represented by the following expressions (1), (2), and (3).

(0°±10°, 0°to20°,a desirable angle of ψ) Expression (1)

(0°±10°, 20°to80°, 0°to60°(1−(θ−50)²/900)^{1/2}) or (0°±10°, 20°to80°,[180°−60°(1−(θ−50)²/900)^{1/2}]to180°) Expression (2)

(0°±10°,[180°−30°(1−(ψ−90)²/8100)^{1/2}]to180°,a desirable angle of ψ) Expression (3)

When the Euler angles are in the range represented by the above-described expressions (1), (2), or (3), a sufficiently wide fractional bandwidth can be obtained, which is desirable.

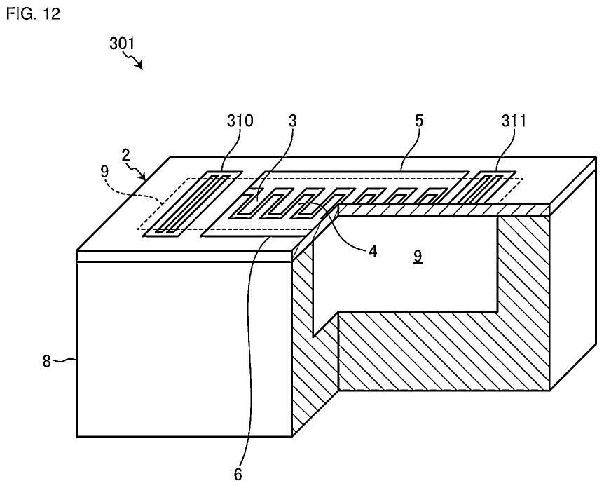

FIG. 12 is a partial cutaway perspective view explaining an acoustic wave device according to an example embodiment of the present disclosure. In FIG. 12, the outer peripheral edges of a space 9 are indicated by the broken lines. An acoustic wave device of an example embodiment of the present invention may be an acoustic wave device utilizing a Lamb wave. In this case, as shown in FIG. 12, an acoustic wave device 301 includes reflectors 310 and 311. The reflector 310 is located on one side of the electrode fingers 3 and 4 on the piezoelectric layer 2 in the acoustic-wave propagating direction, while the reflector 311 is located on the other side of the electrode fingers 3 and 4 in the acoustic-wave propagating direction. In the acoustic wave device 301, a Lamb wave is excited with the application of an AC electric field to the electrode fingers 3 and 4 located above the space 9. Since the reflectors 310 and 311 are located on both sides of the electrode fingers 3 and 4, resonance characteristics based on the Lamb wave can be obtained.

As described above, in the acoustic wave devices 1 and 101, a bulk wave of the thickness shear primary mode is utilized. In the acoustic wave devices 1 and 101, the first and second electrode fingers 3 and 4 are adjacent electrodes, for example, and d/p is set to about 0.5 or smaller, where d is the thickness of the piezoelectric layer 2 and p is the center-to-center distance between the first and second electrode fingers 3 and 4. With this configuration, even if the acoustic wave device is reduced in size, the Q factor can be improved.

In the acoustic wave devices 1 and 101, the piezoelectric layer 2 is preferably made of lithium niobate or lithium tantalate, for example. On the first main surface 2a or the second main surface 2b of the piezoelectric layer 2, the first and second electrode fingers 3 and 4 opposing each other in the direction intersecting with the thickness direction of the piezoelectric layer 2 are located. It is preferable that a protection film cover the first and second electrode fingers 3 and 4.

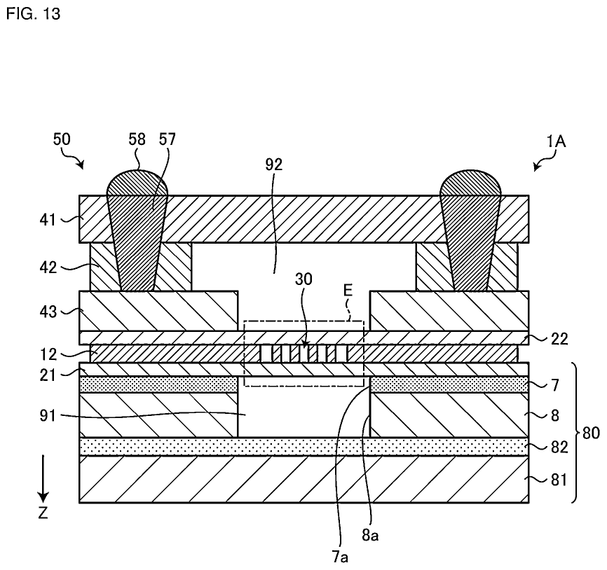

FIG. 13 is a schematic sectional view illustrating a first example of the acoustic wave device of the first example embodiment. As illustrated in FIG. 13, an acoustic wave device 1A according to the first example preferably includes a first piezoelectric layer 21, a second piezoelectric layer 22, a function electrode 30, wiring 12, a support portion 80, a cover layer 41, a support frame 42, a pad 43, and a bump electrode 50. The acoustic wave device 1A according to the first example will be explained below with reference to the drawings. In the following description, an explanation may be given, assuming that, regarding the direction parallel with the Z direction, the orientation in which the support portion 80 is located with respect to the first piezoelectric layer 21 is a downward orientation, while the opposite orientation of the downward orientation is the upward orientation.

The support portion 80 is a member which supports a support substrate 8. In the acoustic wave device 1A of the first example, the support portion 80 includes an intermediate layer 7, the support substrate 8, a cover substrate 81, and a bonding layer 82. The cover substrate 81 is a silicon substrate. The bonding layer 82 is a layer which bonds the cover substrate 81 to the support substrate 8. That is, the cover substrate 81 is located under the support substrate 8 with the bonding layer 82 interposed therebetween. The intermediate layer 7, the cover substrate 81, and the bonding layer 82 are not essential components, and the first piezoelectric layer 21 may contact the top side of the support substrate 8.

The support portion 80 includes a first space 91. The first space 91 defines a portion of the above-described space 9. In the first example, the first space 91 is a space defined by the cavity 7a of the frame-shaped intermediate layer 7 and the cavity 8a of the frame-shaped support substrate 8. In the example in FIG. 13, the first space 91 is closed by the cover substrate 81 and the bonding layer 82. However, this is only an example, and the first space 91 may pass through the support portion 80 if so desired.

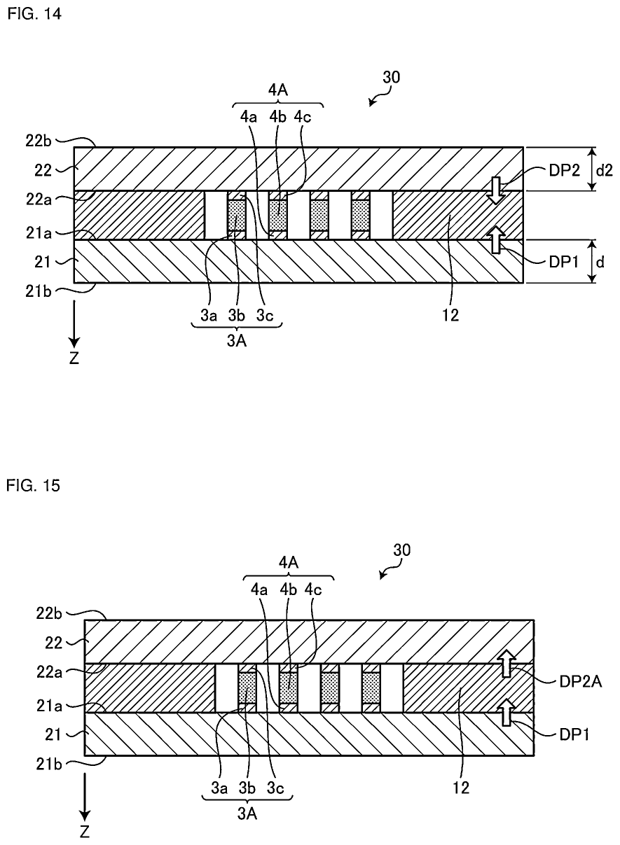

FIG. 14 is an enlarged sectional view illustrating a region E in FIG. 13. The first piezoelectric layer 21, second piezoelectric layer 22, function electrode 30, and wiring 12 will be explained below with reference to FIGS. 13 and 14.

The first piezoelectric layer 21 is a layer made of a piezoelectric body. In the first example, the first piezoelectric layer 21 is located to contact the support portion 80 in the Z direction. As shown in FIG. 14, the first piezoelectric layer 21 includes a first main surface 21a which opposes the second piezoelectric layer 22 and a second main surface 21b located on the opposite side of the first main surface 21a in the Z direction. In the first example, the first main surface 21a contacts the wiring 12 and the function electrode 30. The second main surface 21b opposes the first space 91. In other words, a portion of the second main surface 21b is exposed to the first space 91. In the first example, no layer defined by a conductor, such as an electrode and wiring, is provided on the portion of the second main surface 21b exposed to the first space 91.

The second piezoelectric layer 22 is a layer made of a piezoelectric body. In the first example, the second piezoelectric layer 22 is located on the side of the first main surface 21a of the first piezoelectric layer 21. As shown in FIG. 14, the second piezoelectric layer 22 includes a first main surface 22a which opposes the first piezoelectric layer 21 and a second main surface 22b located on the opposite side of the first main surface 22a in the Z direction. In the first example, the first main surface 22a contacts the wiring 12 and the function electrode 30. The second main surface 22b opposes a second space 92, which will be discussed later. In other words, a portion of the second main surface 22b is exposed to the second space 92. In the first example, no layer defined by a conductor, such as an electrode and wiring, is provided on the portion of the second main surface 22b exposed to the second space 92. Instead of opposing the second space 92, the second main surface 22b may oppose the outside of the acoustic wave device. The entirety of the second main surface 22b may be exposed.

The first piezoelectric layer 21 and the second piezoelectric layer 22 may be made of a material having the same composition. In the first example, the first and second piezoelectric layers 21 and 22 are made of a Z-cut lithium niobate single crystal. This can improve the coupling coefficient.

The polarization state of dielectric polarization of the first main surface 21a of the first piezoelectric layer 21 and that of the first main surface 22a of the second piezoelectric layer 22 are the same. “The polarization state of dielectric polarization of one main surface is the same as that of the other main surface” means that the orientation of the dielectric polarization of one main surface is the same as the orientation of this main surface and that the orientation of the dielectric polarization of the other main surface is the same as the orientation of this main surface. In the first example, the first main surface 21a of the first piezoelectric layer 21 faces upward and the dielectric polarization DP1 of the first main surface 21a of the first piezoelectric layer 21 faces upward. The first main surface 22a of the second piezoelectric layer 22 faces downward and the dielectric polarization DP2 of the first main surface 22a of the second piezoelectric layer 22 faces downward. In this case, the orientation of the dielectric polarization DP1 is the same or substantially the same as that of the first main surface 21a, and the orientation of the dielectric polarization DP2 is the same or substantially the same as that of the first main surface 22a. It can thus be said that the polarization state of the dielectric polarization of the first main surface 21a of the first piezoelectric layer 21 is the same or substantially the same as that of the first main surface 22a of the second piezoelectric layer 22. With this configuration, a high coupling coefficient of the acoustic wave device 1A can be maintained and spurious responses can be reduced. The orientation of the dielectric polarization DP1 of the first main surface 21a may be the opposite orientation of the first main surface 21a, while the orientation of the dielectric polarization DP2 of the first main surface 22a may be the opposite orientation of the first main surface 22a. That is, the dielectric polarization DP1 of the first main surface 21a of the first piezoelectric layer 21 may face downward, while the dielectric polarization DP2 of the first main surface 22a of the second piezoelectric layer 22 may face upward.

The dielectric state of the dielectric polarization of each of the first main surfaces 21a and 22a of the first and second piezoelectric layers 21 and 22 can be examined with a SPM (Scanning Probe Microscopy). More specifically, the first main surfaces 21a and 22a of the first and second piezoelectric layers 21 and 22 are examined with a PRM (Piezo Response Microscope) to determine the orientation of the dielectric polarization. This can determine whether the orientation of the dielectric polarization of the first main surface 21a and that of the first main surface 22a are the same or different.

One of the thickness d of the first piezoelectric layer 21 and the thickness d2 of the second piezoelectric layer 22 does not exceed a dimension about twice as large as the other one of the thickness d and the thickness d2. That is, the thickness d of the first piezoelectric layer 21 does not exceed a dimension about twice as large as the thickness 2d of the second piezoelectric layer 22, and the thickness 2d of the second piezoelectric layer 22 does not exceed a dimension about twice as large as the thickness d of the first piezoelectric layer 21. In other words, the thickness d of the first piezoelectric layer 21 is about half the dimension of the thickness d2 of the second piezoelectric layer 22 or larger and is smaller than the dimension about twice as large as the thickness d2. This makes it less likely to generate a disparity between the coupling of coefficient the first piezoelectric layer 21 and that of the second piezoelectric layer 22, which would be caused by a large difference between the thickness d of the first piezoelectric layer 21 and the thickness 2d of the second piezoelectric layer 22, thus reducing or preventing the degradation of the frequency characteristics. If the thickness d of the first piezoelectric layer 21 and the thickness 2d of the second piezoelectric layer 22 are equal or substantially equal to each other, it is even less likely to generate a disparity between the coupling coefficient of the first piezoelectric layer 21 and that of the second piezoelectric layer 22, which is preferable.

The function electrode 30 is preferably an IDT electrode including a first electrode finger 3A, a second electrode finger 4A, a first busbar electrode 5, and a second busbar electrode 6. The function electrode 30 is located between the first piezoelectric layer 21 and the second piezoelectric layer 22. In the first example, the first electrode finger 3A and the second electrode finger 4A contact the first main surfaces 21a and 22a of the first and second piezoelectric layers 21 and 22. With this configuration, the first and second piezoelectric layers 21 and 22 are excited. Thus, the acoustic wave device 1A can enhance the capacitance while maintaining the same or substantially the same size as a known acoustic wave device, and with the same capacitance as that of a known acoustic wave device, the size of the acoustic wave device 1A can be reduced. Additionally, the electrode fingers 3A and 4A support the portion between the first piezoelectric layer 21 and the second piezoelectric layer 22, thereby improving the mechanical strength of the acoustic wave device 1A.

The first electrode finger 3A is preferably a multilayer body including multiple metal layers 3a, 3b, and 3c stacked on each other in the Z direction. The metal layer 3a is a metal layer of the first electrode finger 3A located on the side of the first piezoelectric layer 21. The metal layer 3a contacts the first main surface 21a of the first piezoelectric layer 21. The metal layer 3a uses, for example, titanium or chromium as a principal component. In other words, the material of the metal layer 3a includes titanium or chromium more than other components. The metal layer 3b is stacked on the metal layer 3a. The material of the metal layer 3b is not limited to a particular material and may be made of a suitable metal or alloy, such as Al or an AlCu alloy, for example. The metal layer 3c is a metal layer of the first electrode finger 3A located on the side of the second piezoelectric layer 22. The metal layer 3c is stacked on the metal layer 3b. The metal layer 3c is made of a material the same as or similar to that of the metal layer 3a and uses titanium or chromium as a principal component. In the first example, the metal layer 3c contacts the first main surface 22a of the second piezoelectric layer 22. This can improve the mechanical strength of the acoustic wave device 1A.

As in the first electrode finger 3A, the second electrode finger 4A is preferably a multilayer body including multiple metal layers 4a, 4b, and 4c stacked on each other in the Z direction. The metal layer 4a is a metal layer of the second electrode finger 4A located on the side of the first piezoelectric layer 21. The metal layer 4a contacts the first main surface 21a of the first piezoelectric layer 21. The metal layer 4a uses, for example, titanium or chromium as a principal component. The metal layer 4b is stacked on the metal layer 4a. The material of the metal layer 4b is not limited to a particular material and may be made of a suitable metal or alloy, such as Al or an AlCu alloy, for example. The metal layer 4c is a metal layer of the second electrode finger 4A located on the side of the second piezoelectric layer 22. The metal layer 4c is stacked on the metal layer 4b. The metal layer 4c is made of a material the same as or similar to that of the metal layer 4a and uses titanium or chromium as a principal component. In the first example, the metal layer 4c contacts the first main surface 22a of the second piezoelectric layer 22. This can improve the mechanical strength of the acoustic wave device 1A.

The wiring 12 is electrically connected to the function electrode 30. The wiring 12 is located between the first piezoelectric layer 21 and the second piezoelectric layer 22. In the first example, the wiring 12 contacts the first main surfaces 21a and 22a of the first and second piezoelectric layers 21 and 22. The wiring 12 is preferably a multilayer body of gold or a gold alloy and another metal, such as titanium, for example, but is not limited thereto. For example, the wiring 12 may be a multilayer body of metal layers made of materials the same as or similar to those of the first and second electrode fingers 3A and 4A.

The pad 43 is electrically connected to the function electrode 30. In the first example, the pad 43 is preferably stacked on the second main surface 22b of the second piezoelectric layer 22. The pad 43 preferably includes, for example, a material made of at least one of the elements selected from Al, Cu, Ti, Pt, Au, Be, and W. This can lower the contact resistance. The pad 43 is preferably an AlCu alloy layer stacked on a contact layer including Ti, for example. In this case, the contact resistance between the pad 43 and the function electrode 30 can be lowered and the cost can also be reduced.

The support frame 42 is preferably stacked on the pad 43 by plating, for example. The support frame 42 is preferably made of Au or an Au alloy, for example. In the first example, the support frame 42 has a frame shape in a plan view in the Z direction. The second space 92 is located inside the support frame 42 in a plan view in the Z direction. The second space 92 is a space between the second piezoelectric layer 22 and the cover layer 41, which will be discussed below.

The cover layer 41 is a silicon substrate, for example. The cover layer 41 is provided to cover the second space 92. The bump electrode 50 is provided in the cover layer 41 at a position at which the bump electrode 50 overlaps the support frame 42 in a plan view in the Z direction.

The bump electrode 50 is located to pass through the cover layer 41 and the support frame 42 in the Z direction. The bump electrode 50 includes a terminal electrode 57 and a bump 58. The terminal electrode 57 is what is known as a bump metal and is electrically connected to the pad 43. The bump 58 is located on the terminal electrode 57. The bump 58 is what is known as a bump metal and is a BGA (ball grid array) bump. The bump 58 is stacked on the terminal electrode 57 in the Z direction and is electrically connected to the terminal electrode 57. With this configuration, the bump 58, terminal electrode 57, pad 43, and function electrode 30 are electrically connected to each other.

The acoustic wave device 1A according to the first example embodiment has been discussed above. However, the acoustic wave device according to the first example embodiment is not limited to the acoustic wave device 1A of the first example. Acoustic wave devices of other examples will be described below with reference to the drawings. Components having the same configurations as those in the first example are designated by like reference numerals and an explanation thereof will be omitted.

FIG. 15 is an enlarged sectional view illustrating a second example of the acoustic wave device of the first example embodiment. FIG. 15 is a sectional view illustrating a region in the second example embodiment corresponding to the region E in FIG. 13. As illustrated in FIG. 15, the acoustic wave device of the second example is different from that of the first example in that the polarization state of the dielectric polarization of the first main surface 21a of the first piezoelectric layer 21 and that of the first main surface 22a of the second piezoelectric layer 22 are different from each other. In the second example, the dielectric polarization DP1 of the first main surface 21a of the first piezoelectric layer 21 faces upward, while the dielectric polarization DP2A of the first main surface 22a of the second piezoelectric layer 22 faces upward. That is, although the orientation of the dielectric polarization DP1 of the first main surface 21a of the first piezoelectric layer 21 is the same as that of the first main surface 21a, the orientation of the dielectric polarization DP2A of the first main surface 22a of the second piezoelectric layer 22 is the opposite orientation of the first main surface 22a. In this case, too, a high coupling coefficient of the acoustic wave device 1A can be maintained. The dielectric polarization DP1 of the first main surface 21a of the first piezoelectric layer 21 may face downward, while the dielectric polarization DP2A of the first main surface 22a of the second piezoelectric layer 22 may face downward.

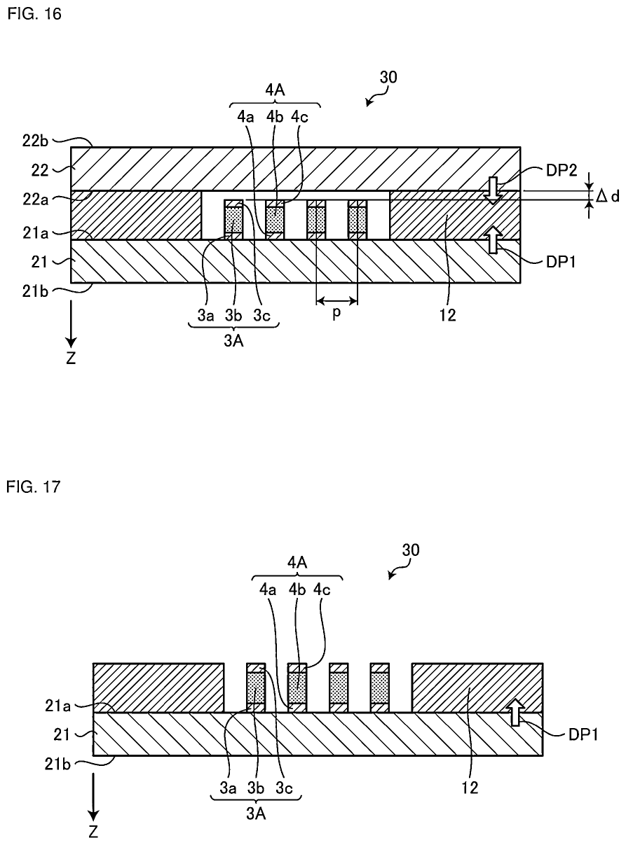

FIG. 16 is an enlarged sectional view illustrating a third example of the acoustic wave device of the first example embodiment. FIG. 16 is a sectional view illustrating a region corresponding to the region E in FIG. 13. As illustrated in FIG. 16, the acoustic wave device of the third example is different from that of the first example in that the second piezoelectric layer 22 does not contact the electrode fingers 3A and 4A. That is, in the third example, there is a gap between the electrode fingers 3A and 4A and the second piezoelectric layer 22. In this case, too, the first and second piezoelectric layers 21 and 22 can be excited by the first and second electrode fingers 3A and 4A.

The distance Δd between at least one of the first and second electrode fingers 3A and 4A and the second piezoelectric layer 22 in the gap is smaller than the center-to-center distance p between the first electrode finger 3A and the second electrode finger 4A. The distance Δd is the shortest distance from the surface of the first electrode finger 3A or the second electrode finger 4A on the side of the second piezoelectric layer 22 to the first main surface 22a of the second piezoelectric layer 22. By setting the distance Δd to this range, the capacitance can be made sufficiently high while the degradation of the frequency characteristics is being reduced of prevented.

The individual examples of the acoustic wave device of the first example embodiment have been described above. However, the acoustic wave device according to the first example embodiment is not limited to the acoustic wave devices of the above-described first through third examples.

In one example, in the third example, the electrode fingers 3A and 4A may contact the first main surface 22a of the second piezoelectric layer 22 and may have a gap with the first piezoelectric layer 21. In this case, the shortest distance from the surface of the first electrode finger 3A or the second electrode finger 4A on the side of the first piezoelectric layer 21 to the first main surface 21a of the first piezoelectric layer 21 corresponds to the distance Δd.

In another example, in the third example, it is not necessary that the first piezoelectric layer 21 and the second piezoelectric layer 22 are bonded to each other via the wiring 12. They may be bonded to each other via an intervening layer made of a material other than a conductor. In this case, too, the mechanical strength of the piezoelectric layers 21 and 22 can be maintained.

In another example, in the third example, a dielectric film may be provided on the surfaces of the electrode fingers 3A and 4A on the side of the second piezoelectric layer 22. In this case, too, the distance from the surface of the electrode finger 3A and/or the electrode finger 4A on the side of the second piezoelectric layer 22 to the first main surface 22a of the second piezoelectric layer 22 is defined as the distance Δd between the electrode finger 3A and/or the electrode finger 4A and the second piezoelectric layer 22 in the gap.

As described above, an acoustic wave device 1A according to the first example includes a first piezoelectric layer 21, a second piezoelectric layer 22 located above the first piezoelectric layer 21 in a first direction, and an IDT electrode. The IDT electrode includes first and second busbar electrodes 5 and 6 and first and second electrode fingers 3A and 4A. The first busbar electrode 5 and the second busbar electrode 6 oppose each other. The first electrode finger 3A is provided for the first busbar electrode 5 and extends toward the second busbar electrode 6. The second electrode finger 4A is provided for the second busbar electrode 6 and extends toward the first busbar electrode 5. The first and second electrode fingers 3A and 4A are sandwiched between the first piezoelectric layer 21 and the second piezoelectric layer 22 in the first direction. The first and second electrode fingers 3A and 4A extend in a second direction which intersects with the first direction and are located to overlap each other as seen in a third direction which is perpendicular or substantially perpendicular to the second direction. With this configuration, the first and second electrode fingers 3A and 4A can excite the first and second piezoelectric layers 21 and 22. The acoustic wave device 1A can thus improve the capacitance while maintaining the same size as a known acoustic wave device. With the same or substantially the same capacitance as that of a known acoustic wave device, the size of the acoustic wave device 1A can be reduced.

In a preferable mode, in the first direction, the first and second electrode fingers 3A and 4A contact the first and second piezoelectric layers 21 and 22. With this configuration, the first and second electrode fingers 3A and 4A support the portion between the first piezoelectric layer 21 and the second piezoelectric layer 22 in the Z direction, thereby improving the mechanical strength of the acoustic wave device 1A.

In the first direction, the first and second electrode fingers 3A and 4A may contact the first piezoelectric layer 21 and have a gap with the second piezoelectric layer 22. In this case, too, the first and second electrode fingers 3A and 4A can excite the first and second piezoelectric layers 21 and 22. The acoustic wave device 1A can thus enhance the capacitance while maintaining the same size as a known acoustic wave device. With the same capacitance as that of a known acoustic wave device, the size of the acoustic wave device 1A can be reduced.

In a preferable mode, the distance Δd between at least one of the first and second electrode fingers 3A and 4A and the second piezoelectric layer 22 in the gap is smaller than the center-to-center distance p between the first electrode finger 3A and the second electrode finger 4A. With this configuration, the capacitance can be made sufficiently high while the degradation of the frequency characteristics is reduced or prevent.

In a preferable mode, the first and second piezoelectric layers 21 and 22 are made of the same material. This can improve the coupling coefficient.

In a preferable mode, the first and second piezoelectric layers 21 and 22 are made of a single crystal and the polarization state of dielectric polarization of a main surface of the first piezoelectric layer 21 is the same as that of a main surface of the second piezoelectric layer 22. The main surfaces of the first and second piezoelectric layers 21 and 22 oppose each other. With this configuration, a high coupling coefficient of the acoustic wave device 1A can be maintained and spurious responses can be reduced.

In a preferable mode, one of the thickness d of the first piezoelectric layer 21 and the thickness d2 of the second piezoelectric layer 22 does not exceed a dimension twice as large as the other one of the thickness d and the thickness d2. This makes it less likely to generate a disparity between the coupling coefficient of the first piezoelectric layer 21 and that of the second piezoelectric layer 22, which would be caused by a difference between the thickness of the first piezoelectric layer 21 and that of the second piezoelectric layer 22, thus reducing or preventing the degradation of the frequency characteristics.

In a preferable mode, the first electrode finger 3A is a multilayer body including plural metal layers 3a through 3c, and the second electrode finger 4A is a multilayer body including plural metal layers 4a through 4c. The metal layers 3a and 3c of the first electrode finger 3A and the metal layers 4a and 4c of the second electrode finger 4A contact the first piezoelectric layer 21 or the second piezoelectric layer 22. The metal layers 3a, 3c, 4a, and 4c include titanium or chromium as a principal component. This can improve the mechanical strength of the acoustic wave device 1A.

In a preferable mode, the acoustic wave device 1A also includes a support portion 80. The support portion 80 includes a space (space 91). The first piezoelectric layer 21 is located on the support portion 80 in the first direction. The first piezoelectric layer 21 includes first and second main surfaces 21a and 21b. The first main surface 21a opposes the second piezoelectric layer 22. The second main surface 21b is located on the opposite side of the first main surface 21a in the first direction. The second main surface 21b of the first piezoelectric layer 21 opposes the space. This makes it less likely to interfere with the vibration of the first piezoelectric layer 21 in the excitation region.

In a preferable mode, at least, the thickness of the first piezoelectric layer 21 is 2p or smaller, where p is the center-to-center distance between adjacent first and second electrode fingers 3A and 4A of the first and second electrode fingers 3A and 4A. This can effectively excite a bulk wave of the thickness shear primary mode.

In a preferable mode, the first and second piezoelectric layers 21 and 22 include lithium niobate or lithium tantalate. This makes it possible to provide an acoustic wave device that can exhibit high resonance characteristics.

In a preferable mode, the acoustic wave device is able to use a bulk wave of the thickness shear mode. Using a Lamb wave may affect the frequency characteristics when the function electrode 30 is made thick. Conversely, using a bulk wave of the thickness shear mode does not affect the frequency characteristics considerably even when the function electrode 30 is made thick. The thickness of the function electrode 30 can thus be increased, thus reducing a loss due to series resistance.

In a preferable mode, d/p is about 0.24 or smaller. This can excite a bulk wave of the thickness shear primary mode more effectively.

In a preferable mode, d/p≤ about 0.5 is satisfied, where d is the thickness of the first piezoelectric layer 21 and p is the center-to-center distance between adjacent first and second electrode fingers 3A and 4A of the first and second electrode fingers 3A and 4A. This can effectively excite a bulk wave of the thickness shear primary mode.

In a preferable mode, MR ≤about 1.75 (d/p)+0.075 is satisfied, where MR is a metallization ratio of the area of the first and second electrode fingers 3A and 4A within the excitation region to the area of the excitation region. The excitation region is a region in which the first and second electrode fingers 3A and 4A overlap each other as seen in the third direction. This can reduce spurious responses effectively.

In a preferable mode, the first and second piezoelectric layers 21 and 22 contain lithium niobate or lithium tantalate. The Euler angles (φ, θ, ψ) of lithium niobate or lithium tantalate are in a range represented by expression (1), (2), or (3). This can reliably make the fractional bandwidth be about 17% or lower.

(0°±10°, 0°to20°,a desirable angle of ψ) Expression (1)

(0°±10°, 20°to80°, 0°to60°(1−(θ−50)²/900)^{1/2}) or (0°±10°, 20°to80°,[180°−60°(1−(θ−50)²/900)^{1/2}]to180°) Expression (2)

(0°±10°,[180°−30°(1−(ψ−90)²/8100)^{1/2}]to180°,a desirable angle of ψ) Expression (3)

Tests according to the present disclosure will be described below.

In the tests, acoustic wave devices of first and second test examples and first and second comparative examples were simulated using the finite element method, and admittance characteristics were calculated.

The acoustic wave device of the first test example is the acoustic wave device 1A of the first example. The design parameters of the acoustic wave device of the first test example are as follows.
First and second piezoelectric layers 21 and 22: LiNbO₃ single crystal having the Euler angles of (0°, 0°, 90°)
Thickness d of the first piezoelectric layer 21: about 400 nm
Thickness 2d of the second piezoelectric layer 22: about 400 nm
Center-to-center distance p between electrode fingers 3A and 4A: about 3.55 μm
Width of electrode fingers 3A and 4A: about 1.1 μm
Metal layers 3a and 4a of electrode fingers 3A and 4A: titanium having a thickness of about 10 nm
Metal layers 3b and 4b of electrode fingers 3A and 4A: aluminum having a thickness of about 490 nm
Metal layers 3c and 4c of electrode fingers 3A and 4A: titanium having a thickness of about 10 nm

The acoustic wave device of the second test example is the acoustic wave device of the second example. That is, in the acoustic wave device of the second test example, the orientation of the dielectric polarization of the first main surface 22a of the second piezoelectric layer 22 is different from that in the first test example. The other design parameters of the acoustic wave device of the second test example are similar to those of the first test example.

FIG. 17 is an enlarged sectional view illustrating the acoustic wave device of the first comparative example. FIG. 17 is a sectional view illustrating a region corresponding to the region E in FIG. 13. As illustrated in FIG. 17, the acoustic wave device of the first comparative example is different from that of the first test example in that the second piezoelectric layer 22 is not provided. The other design parameters of the acoustic wave device of the first comparative example are similar to those of the first test example.

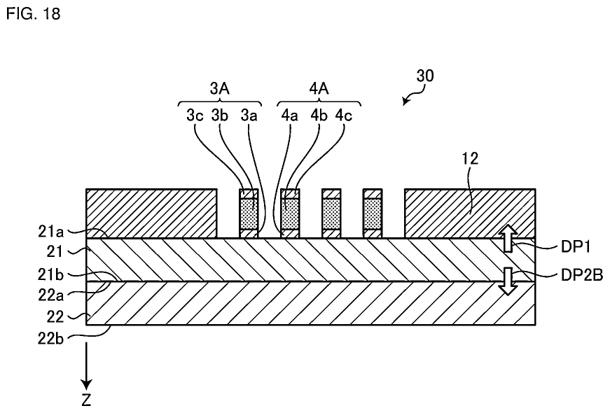

FIG. 18 is an enlarged sectional view illustrating the acoustic wave device of the second comparative example. FIG. 18 is a sectional view illustrating a region corresponding to the region E in FIG. 13. As illustrated in FIG. 18, the acoustic wave device of the second comparative example is different from that of the first test example in that the second piezoelectric layer 22 is provided on the side of the second main surface 21b of the first piezoelectric layer 21. The other design parameters of the acoustic wave device of the second comparative example are similar to those of the first test example.

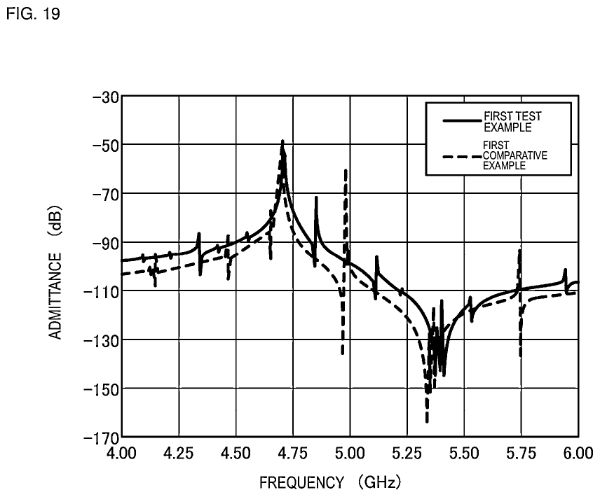

FIG. 19 is a graph illustrating the admittance characteristics of the acoustic wave devices of the first test example and the first comparative example. As shown in FIG. 19, the capacitance of the acoustic wave device of the first test example is increased while a coupling coefficient higher than or equal to that of the first comparative example is maintained. The capacitance of the acoustic wave device of the first test example is increased by about 97%, compared with that of the first comparative example. The reason for this may be that the second piezoelectric layer 22 is provided in the acoustic wave device of the first test example. By reducing the element size of the acoustic wave device of the first test example into half of that of the first comparative example, substantially the same capacitance can be obtained. In this manner, the acoustic wave device of the first test example can be reduced in size.

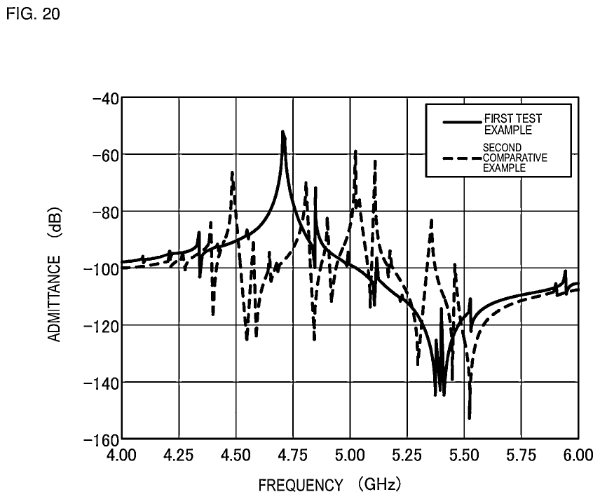

FIG. 20 is a graph illustrating the admittance characteristics of the acoustic wave devices of the first test example and the second comparative example. As shown in FIG. 20, the capacitance of the acoustic wave device of the first test example is increased by about 52%, compared with that of the second comparative example. The reason for this may be that the distance between the electrode fingers 3 and 4 and the second piezoelectric layer 22 in the acoustic wave device of the first test example is closer than that in the second comparative example. Even if the element size of the acoustic wave device of the first test example is made smaller than that of the second comparative example, the same capacitance can be obtained. As a result, the acoustic wave device of the first test example can be reduced in size.

Additionally, as illustrated in FIG. 20, in the acoustic wave device of the first test example, spurious responses due to an electric field in the thickness direction are lowered compared with those of the acoustic wave device of the second comparative example. The reason for this may be that the ratio of the thickness d to the center-to-center distance p in the acoustic wave device of the first test example is about half of that of the second comparative example, which is suitable for the mode generated in the piezoelectric layer. As a result, the acoustic wave device of the first test example can reduce spurious responses compared with the acoustic wave device of the second comparative example.

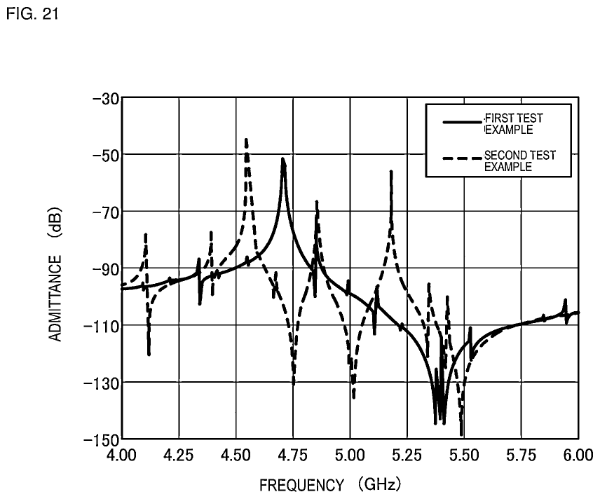

FIG. 21 is a graph illustrating the admittance characteristics of the acoustic wave devices of the first and second test examples. As shown in FIG. 21, more spurious responses are observed in the second test example than those in the first test example because the state of the dielectric polarization of the first main surface 21a of the first piezoelectric layer 21 is different from that of the first main surface 22a of the second piezoelectric layer 22 in the second test example. Yet, about the same capacitance as that of the acoustic wave device of the first test example is obtained in the second test example. As a result, the acoustic wave device of the second test example can also be reduced in size.

The above-described example embodiments are provided to facilitate the understanding of the disclosure, but is not intended to be exhaustive or to limit the disclosure to the precise forms disclosed. Modifications/improvements may be made without departing from the spirit and scope of the disclosure, and equivalents of the disclosure are also encompassed in the disclosure.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first piezoelectric layer;
a second piezoelectric layer located above the first piezoelectric layer in a first direction; and
an interdigital transducer (IDT) electrode; wherein
the IDT electrode includes first and second busbar electrodes and first and second electrode fingers, the first busbar electrode and the second busbar electrode opposing each other, the first electrode finger being provided to the first busbar electrode and extending toward the second busbar electrode, the second electrode finger being provided to the second busbar electrode and extending toward the first busbar electrode; and
the first and second electrode fingers are sandwiched between the first piezoelectric layer and the second piezoelectric layer in the first direction, and the first and second electrode fingers extend in a second direction which intersects with the first direction and are located to overlap each other as seen in a third direction which is perpendicular or substantially perpendicular to the second direction.

2. The acoustic wave device according to claim 1, wherein, in the first direction, the first and second electrode fingers contact the first and second piezoelectric layers.

3. The acoustic wave device according to claim 1, wherein, in the first direction, the first and second electrode fingers contact the first piezoelectric layer and include a gap with the second piezoelectric layer.

4. The acoustic wave device according to claim 3, wherein a distance between at least one of the first and second electrode fingers and the second piezoelectric layer in the gap is smaller than a center-to-center distance between the first electrode finger and the second electrode finger.

5. The acoustic wave device according to claim 1, wherein the first and second piezoelectric layers are made of a same material.

6. The acoustic wave device according to claim 1, wherein the first and second piezoelectric layers are made of a single crystal and a polarization state of dielectric polarization of a main surface of the first piezoelectric layer is identical or substantially identical to a polarization state of dielectric polarization of a main surface of the second piezoelectric layer, the main surface of the first piezoelectric layer and the main surface of the second piezoelectric layer opposing each other.

7. The acoustic wave device according to claim 1, wherein a thickness of one of the first and second piezoelectric layers does not exceed a dimension about twice as large as a thickness of the other one of the first and second piezoelectric layers.

8. The acoustic wave device according to claim 1, wherein
each of the first and second electrode fingers is a multilayer body including a plurality of metal layers; and
a metal layer of the plurality of metal layers of the first electrode finger and a metal layer of the plurality of metal layers of the second electrode finger contact at least one of the first piezoelectric layer or the second piezoelectric layer, and the metal layers which contact the first or second piezoelectric layer include titanium or chromium as a principal component.

9. The acoustic wave device according to claim 1, further comprising:
a support portion; wherein
the support portion includes a space;
the first piezoelectric layer is located above the support portion in the first direction;
the first piezoelectric layer includes first and second main surfaces, the first main surface opposing the second piezoelectric layer, the second main surface being located on an opposite side of the first main surface in the first direction; and
the second main surface of the first piezoelectric layer opposes the space.

10. The acoustic wave device according to claim 1, wherein the first and second piezoelectric layers include lithium niobate or lithium tantalate.

11. The acoustic wave device according to claim 1, wherein a thickness of the first piezoelectric layer is about 2p or smaller, where p is a center-to-center distance between adjacent first and second electrode fingers of the first and second electrode fingers.

12. The acoustic wave device according to claim 1, wherein the acoustic wave device structured to generate a bulk wave of a thickness shear mode.

13. The acoustic wave device according to claim 1, wherein d/p≤ about 0.5 is satisfied, where d is a thickness of the first piezoelectric layer.

14. The acoustic wave device according to claim 13, wherein d/p is about 0.24 or smaller.

15. The acoustic wave device according to claim 1, wherein MR ≤about 1.75 (d/p)+0.075 is satisfied, where MR is a metallization ratio of an area of the first and second electrode fingers within an excitation region to an area of the excitation region, the excitation region being a region in which the first and second electrode fingers overlap each other as seen in the third direction.

16. The acoustic wave device according to claim 1, wherein
the first and second piezoelectric layers include lithium niobate or lithium tantalate; and
Euler angles (φ, θ, ψ) of the lithium niobate or the lithium tantalate are in a range represented by at least one of the following expressions:
(0°±10°, 0° to 20°, a desirable angle of ψ);
(0°±10°, 20° to 80°, 0° to 60° (1−(θ−50)²/900)^{1/2}) or (0°±10°, 20° to 80°, [180°−60° (1−(θ−50)²/900)^{1/2}] to)180°; and
(0°±10°, [180°−30° (1−(ψ−90)²/8100)^{1/2}] to 180°, a desirable angle of ψ).

17. The acoustic wave device according to claim 9, wherein
the support portion includes an intermediate layer and a support substrate, the intermediate layer being provided between the support substrate and the first piezoelectric layer; and
the intermediate layer and the support substrate both have a frame shape.

18. The acoustic wave device according to claim 17, wherein the space is defined by a cavity of the intermediate layer and a cavity of the support substrate which are closed by a cover substrate.

19. The acoustic wave device according to claim 1, wherein a center-to-center distance of an adjacent pair of the first electrode fingers is the same or substantially the same as a center-to-center distance of an adjacent pair of the second electrode fingers.

20. The acoustic wave device according to claim 1, wherein a thickness of the first piezoelectric layer does not exceed a dimension about twice as large as a thickness of the second piezoelectric layer, and the thickness of the second piezoelectric layer does not exceed a dimension about twice as large as the thickness of the first piezoelectric layer.
